(19) United States
(12) Patent Application Publication
(10) Pub. No.: US 2017/0280590 A1
(43) Pub. Date: Sep. 28, 2017

(54) PHASE-CHANGE COOLING DEVICE AND PHASE-CHANGE COOLING METHOD

(71) Applicant: NEC Corporation, Tokyo (JP)

(72) Inventors: Masaki CHIBA, Tokyo (JP); Minoru YOSHIKAWA, Tokyo (JP); Akira SHOUJIGUCHI, Tokyo (JP); Arihiro MATSUNAGA, Tokyo (JP); Masanori SATO, Tokyo (JP)

(73) Assignee: NEC Corporation, Tokyo (JP)

(21) Appl. No.: 15/506,513

(22) PCT Filed: Aug. 19, 2015
(86) PCT No.: PCT/JP2015/004144

§ 371 Date: Feb. 24, 2017

(30) Foreign Application Priority Data
Aug. 27, 2014 (JP) 2014-172114

(51) Int. Cl. H05K 7/20; F28D 15/02

(52) U.S. Cl. CPC H05K 7/20327; F28D 15/0266; H05K 7/20318

(57) ABSTRACT

In a natural-circulation type phase-change cooling device, the cooling performance is degraded if the number of heat sources to be cooled increases; therefore, a phase-change cooling device according to an exemplary aspect of the present invention includes a plurality of heat receiving units for respectively holding refrigerant receiving heat from a plurality of heat sources; a condensing unit for generating refrigerant liquid by condensing and liquefying refrigerant vapor of the refrigerant evaporated in the heat receiving units; a refrigerant vapor transport structure configured to connect the heat receiving units to the condensing unit and transport the refrigerant vapor; a refrigerant liquid transport structure configured to connect the heat receiving units to the condensing unit and transport the refrigerant liquid; wherein the refrigerant vapor transport structure includes a plurality of sub-vapor-pipes respectively connected to the plurality of heat receiving units, a vapor joining portion connected to the plurality of sub-vapor-pipes, with the refrigerant vapor meeting, and a main-vapor-pipe connecting the vapor joining portion to the condensing unit.

### TECHNICAL FIELD

The present invention relates to phase-change cooling devices and phase-change cooling methods used for cooling electronic devices, and the like, in particular, to a phase-change cooling device and a phase-change cooling method employing natural circulation in which refrigerant vapor phase-changed by heat receiving is transported without a driving source and condensed.

### BACKGROUND ART

In recent years, the required amount of information processing has increased with the improvement in information processing technologies and the rise of the Internet environment. Data centers (DCs) are installed and operated in various places in order to process huge volumes of data. Here, the data center (DC) means a specialized facility for installing and operating severs and data communication devices. In the data centers (DCs), the density of heat generation by electronic devices such as a server and a data communication device is extremely high; consequently, it is necessary to cool these electronic devices efficiently.

A natural-circulation type phase-change cooling system has been known as an example of efficient cooling systems for electronic devices and the like (see, Patent Literature 1, for example). In the natural-circulation type phase-change cooling system, the heat generated by a heat source such as an electronic device is received and radiated using the latent heat of refrigerant. This system makes it possible to drive the refrigerant circularly without power supply because of the buoyancy of refrigerant vapor and the gravity of refrigerant liquid. Accordingly, the natural-circulation type phase-change cooling system enables efficient and energy-saving cooling of electronic devices and the like.

An example of a natural-circulation type phase-change cooling device is described in Patent Literature 1. A related cooling system disclosed in Patent Literature 1 includes evaporators set respectively in a plurality of servers, a cooling tower installed on the roof of a building, a return pipe (refrigerant gas pipe), and a supply pipe (refrigerant liquid pipe). The return pipe and the supply pipe connect cooling coils set in the evaporators to a spiral pipe set in the cooling tower. The return pipe returns the refrigerant gas vaporized in the evaporators to the cooling tower. The supply pipe supplies the evaporators with the refrigerant liquid that is liquefied resulting from cooling and condensing the refrigerant gas in the cooling tower. This forms a circulation line through which the refrigerant circulates naturally, between the evaporators and the cooling tower.

Each evaporator is provided with a temperature sensor to measure the temperature of the air that results from cooling, in the evaporator, the high temperature air exhausted from a server. At the outlet of the cooling coil in each of the evaporators, a valve (flow adjustment means) is provided that adjusts the supply flow rate of the refrigerant supplied to the cooling coil (refrigerant flow). A controller automatically adjusts the degree of opening of each valve based on the temperature measured by the temperature sensor. This enables the supply flow rate of the refrigerant to decrease by narrowing the opening of the valve if the temperature of the air that has been cooled in the evaporators becomes too lower than a predetermined temperature.

It is said that, according to the related cooling system, the above-described configuration keeps the supply flow rate of the refrigerant in each evaporator from increasing more than necessary; accordingly, it is possible to reduce the cooling load of the refrigerant and achieve a sufficient cooling performance by using a cooling tower only.

### CITATION LIST

### Patent Literature

[PTL 1] Japanese Unexamined Patent Application Publication No. 2009-194093 (paragraphs [0047] to [0055], FIG. 1)

### SUMMARY OF INVENTION

### Technical Problem

In the above-mentioned related cooling system described in Patent Literature 1, the return pipe (refrigerant gas pipe) and the supply pipe, branching on the way, are connected to the evaporators provided for the servers installed on the first floor and the evaporators provided for the servers installed on the second floor. Consequently, the number of branches of the refrigerant vapor pipe increases if the number of heat sources to be cooled increases. As mentioned above, in a natural-circulation type phase-change cooling device, the refrigerant naturally circulates because of the pressure difference of the refrigerant vapor arising between the evaporators and the cooling tower (condensing unit), and gravity acting on the condensed refrigerant liquid. Consequently, if the number of branches of the refrigerant vapor pipe increases due to the increase in the number of heat sources to be cooled, the pressure loss of the refrigerant vapor increases due to the confluence of the refrigerant vapor at the branch points, which results in the problem that the cooling performance is degraded.

Thus, there has been the problem that the cooling performance is degraded in a natural-circulation type phase-change cooling device if the number of heat sources to be cooled increases.

The object of the present invention is to provide a phase-change cooling device and a phase-change cooling method that solve the above-mentioned problem that the cooling performance is degraded in a natural-circulation type phase-change cooling device if the number of heat sources to be cooled increases.

### Solution to Problem

A phase-change cooling device according to an exemplary aspect of the present invention includes a plurality of heat receiving units for receiving heat; a condensing unit for radiating heat; and a first refrigerant pathway and a second refrigerant pathway connecting the plurality of heat receiving units to the condensing unit; wherein the first refrigerant pathway includes a plurality of sub-refrigerant-pipes respectively connected to the plurality of heat receiving units, a refrigerant joining unit connected to the plurality of sub-refrigerant-pipes, and a main-refrigerant-pipe connecting the refrigerant joining unit to the condensing unit.

A phase-change cooling device according to an exemplary aspect of the present invention includes a plurality of heat receiving units for respectively holding refrigerant receiving heat from a plurality of heat sources; a condensing unit for generating refrigerant liquid by condensing and liquefying refrigerant vapor of the refrigerant evaporated in the heat receiving units; a refrigerant vapor transport structure configured to connect the heat receiving units to the condensing unit and transport the refrigerant vapor; a refrigerant liquid transport structure configured to connect the heat receiving units to the condensing unit and transport the refrigerant liquid; wherein the refrigerant vapor transport structure includes a plurality of sub-vapor-pipes respectively connected to the plurality of heat receiving units, a vapor joining portion connected to the plurality of sub-vapor-pipes, with the refrigerant vapor meeting, and a main-vapor-pipe connecting the vapor joining portion to the condensing unit.

A phase-change cooling method according to an exemplary aspect of the present invention includes evaporating refrigerant by receiving heat from each of a plurality of heat sources, making refrigerant vapor streams of the refrigerant evaporated by each of the plurality of heat sources meet; generating refrigerant liquid by condensing and liquefying joined refrigerant vapor; and circulating the refrigerant liquid so as to receive heat from each of the plurality of heat sources.

### Advantageous Effects of Invention

According to the phase-change cooling device and the phase-change cooling method of the present invention, it is possible to cool efficiently even a plurality of heat sources to be cooled by a natural-circulation type phase-change cooling system without degrading the cooling performance.

### BRIEF DESCRIPTION OF DRAWINGS

FIG. 1 is a schematic view illustrating a configuration of a phase-change cooling device in accordance with a first example embodiment of the present invention.

FIG. 2 is a schematic view illustrating a configuration of a refrigerant vapor transport structure in accordance with a second example embodiment of the present invention.

FIG. 3 is a perspective view illustrating a configuration of a vapor joining portion included in the refrigerant vapor transport structure in accordance with the second example embodiment of the present invention.

FIG. 4 is a perspective view illustrating another configuration of the vapor joining portion included in the refrigerant vapor transport structure in accordance with the second example embodiment of the present invention.

FIG. 5 is a perspective view illustrating yet another configuration of the vapor joining portion included in the refrigerant vapor transport structure in accordance with the second example embodiment of the present invention.

FIG. 6 is a schematic view illustrating a configuration of a refrigerant vapor transport structure in accordance with a third example embodiment of the present invention.

FIG. 7A is a side view illustrating a configuration of the vapor joining portion included in the refrigerant vapor transport structure in accordance with the third example embodiment of the present invention.

FIG. 7B is a top view illustrating a configuration of the vapor joining portion included in the refrigerant vapor transport structure in accordance with the third example embodiment of the present invention.

FIG. 8 is a side view illustrating another configuration of the vapor joining portion included in the refrigerant vapor transport structure in accordance with the third example embodiment of the present invention.

FIG. 9 is a side view illustrating yet another configuration of the vapor joining portion included in the refrigerant vapor transport structure in accordance with the third example embodiment of the present invention.

FIG. 10 is a schematic view of the refrigerant vapor transport structure in accordance with the third example embodiment of the present invention.

### EXAMPLE EMBODIMENT

Example embodiments of the present invention will be described below with reference to drawings.

### A First Example Embodiment

A phase-change cooling device in accordance with a first example embodiment of the present invention includes a plurality of heat receiving units for receiving heat, a condensing unit for radiating heat, a first refrigerant pathway, and a second refrigerant pathway connecting the plurality of heat receiving units to the condensing unit. The first refrigerant pathway includes a plurality of sub-refrigerant-pipes respectively connected to the plurality of heat receiving units, a refrigerant joining portion connected to the plurality of sub-refrigerant-pipes, and a main-refrigerant-pipe connecting the refrigerant joining portion to the condensing unit.

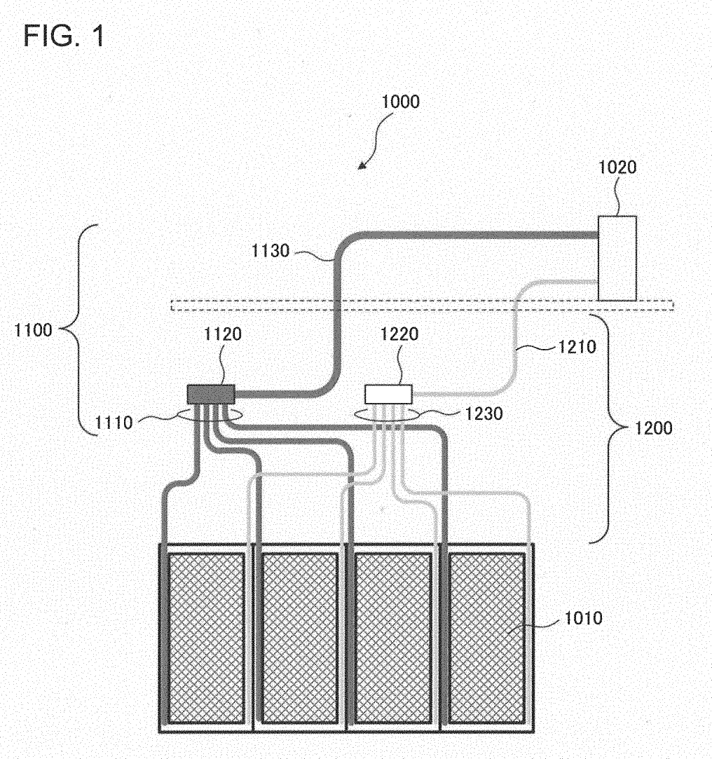

The phase-change cooling device in accordance with the first example embodiment of the present invention will be described further in detail. FIG. 1 is a schematic view illustrating the configuration of a phase-change cooling device 1000 in accordance with the first example embodiment of the present invention. The phase-change cooling device 1000 according to the present example embodiment includes a plurality of heat receiving units 1010, a condensing unit 1020, a refrigerant vapor transport structure (a first refrigerant pathway) 1100, and a refrigerant liquid transport structure (a second refrigerant pathway) 1200.

The plurality of heat receiving units 1010 respectively hold refrigerant that receives heat from a plurality of heat sources. The condensing unit 1020 generates refrigerant liquid by condensing and liquefying refrigerant vapor of the refrigerant evaporated in the heat receiving units 1010. The refrigerant vapor transport structure 1100 connects the heat receiving units 1010 to the condensing unit 1020 and transports the refrigerant vapor. The refrigerant liquid transport structure 1200 connects the heat receiving units 1010 to the condensing unit 1020 and transports the refrigerant liquid.

The refrigerant vapor transport structure 1100 includes a plurality of sub-vapor-pipes (sub-refrigerant-pipes) 1110, a vapor joining portion (refrigerant joining portion) 1120, and a main-vapor-pipe (main-refrigerant-pipe) 1130. The plurality of sub-vapor-pipes 1110 are respectively connected to the plurality of heat receiving units 1010. The plurality of sub-vapor-pipes 1110 are connected to the vapor joining portion 1120, where the refrigerant vapor streams meet that flow in through the plurality of sub-vapor-pipes 1110 and have been generated in the respective heat receiving units 1010. The main-vapor-pipe 1130 connects the vapor joining portion 1120 to the condensing unit 1020.

As mentioned above, the phase-change cooling device 1000 according to the present example embodiment is configured to include the vapor joining portion 1120 in the refrigerant vapor transport structure 1100, and connect the vapor joining portion 1120 to the plurality of heat receiving units 1010 respectively by the plurality of sub-vapor-pipes 1110. This enables the refrigerant vapor generated by the plurality of heat sources to meet in the vapor joining portion 1120; therefore, it is possible to reduce the pressure loss due to a branching. As a result, according to the phase-change cooling device 1000 of the present example embodiment, it is possible to cool efficiently even a plurality of heat sources to be cooled by a natural-circulation type phase-change cooling system without degrading the cooling performance.

As illustrated in FIG. 1, the vapor joining portion 1120 can be configured to be positioned above the plurality of heat receiving units 1010 in the vertical. This enables the refrigerant vapor to flow from the plurality of heat receiving units 1010 to the vapor joining portion 1120 only by the action of buoyancy of the refrigerant vapor.

The configuration of the refrigerant liquid transport structure 1200 is not particularly limited; however, as illustrated in FIG. 1, it can be configured to include a main-liquid-pipe 1210, a refrigerant liquid reservoir 1220, and a plurality of sub-liquid-pipes 1230, for example. The main-liquid-pipe 1210 is connected to the condensing unit 1020. The refrigerant liquid reservoir 1220 is connected to the main-liquid-pipe 1210 and stores refrigerant liquid. The plurality of sub-liquid-pipes 1230 respectively connect the refrigerant liquid reservoir 1220 to the plurality of heat receiving units 1010.

The heat receiving units 1010 can be configured to include a plurality of evaporating units each of which is thermally connected to a heat source and stores the refrigerant, and it can be configured in which the plurality of evaporating units are disposed in the vertical direction. Specifically, for example, the heat receiving unit 1010 can be a heat receiving module in which a plurality of servers as heat sources are disposed in a stack within a server rack, which includes the evaporating unit on a rear door or the like of the server rack. The vapor joining portion 1120 can be configured to be positioned above the server rack, outside the rear door on which the heat receiving unit 1010 is disposed. The refrigerant liquid reservoir 1220 can also be configured to be positioned above the server rack, outside the rear door on which the heat receiving unit 1010 is disposed.

Next, the operation of the phase-change cooling device 1000 according to the present example embodiment will be described using the configuration illustrated in FIG. 1 as an example.

The phase-change cooling device 1000 absorbs the heat that is generated in a plurality of servers disposed in the server rack, for example, by means of the heat receiving units 1010 included in respective server racks, and radiates the heat by the condensing unit 1020. This makes it possible to cool the servers and the like installed in the server rack.

Each of the heat receiving units 1010, which is provided in each server rack and absorbs the heat from the server rack, is connected to the sub-vapor-pipe 1110 and the sub-liquid-pipe 1230. The sub-vapor-pipe 1110 is connected to the main-vapor-pipe 1130 at the vapor joining portion 1120, and the sub-liquid-pipe 1230 is connected to the main-liquid-pipe 1210 at the refrigerant liquid reservoir 1220. The main-vapor-pipe 1130 and the main-liquid-pipe 1210 are connected to the single condensing unit 1020

The heat receiving unit 1010 is filled with the refrigerant liquid. The refrigerant liquid receives the exhaust heat from the server rack, and absorbs the heat, and vaporizes, by which the refrigerant liquid turns to the refrigerant vapor and rises by buoyancy. The refrigerant vapor flows toward the condensing unit 1020 through the sub-vapor-pipes 1110 with less pressure loss than the sub-liquid-pipe 1230. At this time, the refrigerant vapor streams from the respective heat receiving units 1010 meet in the vapor joining portion 1120 and then reach the condensing unit 1020 through the main-vapor-pipe 1130.

The refrigerant vapor radiates the heat in the condensing unit 1020 by exchanging the heat for air or water. The refrigerant condensed and liquefied in the condensing unit 1020 turns to refrigerant liquid, which flows toward the refrigerant liquid reservoir 1220 through the main-liquid-pipe 1210. The refrigerant liquid is distributed from the refrigerant liquid reservoir 1220 to the respective heat receiving units 1010, and the needed volume of the refrigerant liquid is supplied for each heat receiving unit 1010 through the sub-liquid-pipes 1230. This cooling cycle is continuously performed, which makes it possible to absorb the heat continuously from the server rack.

There can be not only refrigerant vapor but also refrigerant liquid in the sub-vapor-pipes 1110, the vapor joining portion 1120, and the main-vapor-pipe 1130, which compose the refrigerant vapor transport structure 1100. Similarly, there can be not only refrigerant liquid but also refrigerant vapor in the main-liquid-pipe 1210, the refrigerant liquid reservoir 1220, and the sub-liquid-pipes 1230, which compose the refrigerant liquid transport structure 1200.

Next, a phase-change cooling method according to the present example embodiment will be described.

In a phase-change cooling method according to the present example embodiment, first, refrigerant is evaporated by receiving heat from each of a plurality of heat sources, and refrigerant vapor streams of the refrigerant evaporated by each of the plurality of heat sources are made to meet. And then, refrigerant liquid is generated by condensing and liquefying the joined refrigerant vapor, and the refrigerant liquid is circulated so as to receive heat from each of the plurality of heat sources. This makes it possible to cool efficiently even a plurality of heat sources to be cooled by a natural-circulation type phase-change cooling system without degrading the cooling performance.

### A Second Example Embodiment

Next, a second example embodiment of the present invention will be described. In the present example embodiment, the refrigerant vapor transport structure 1100 included in the phase-change cooling device 1000 will be described further in detail.

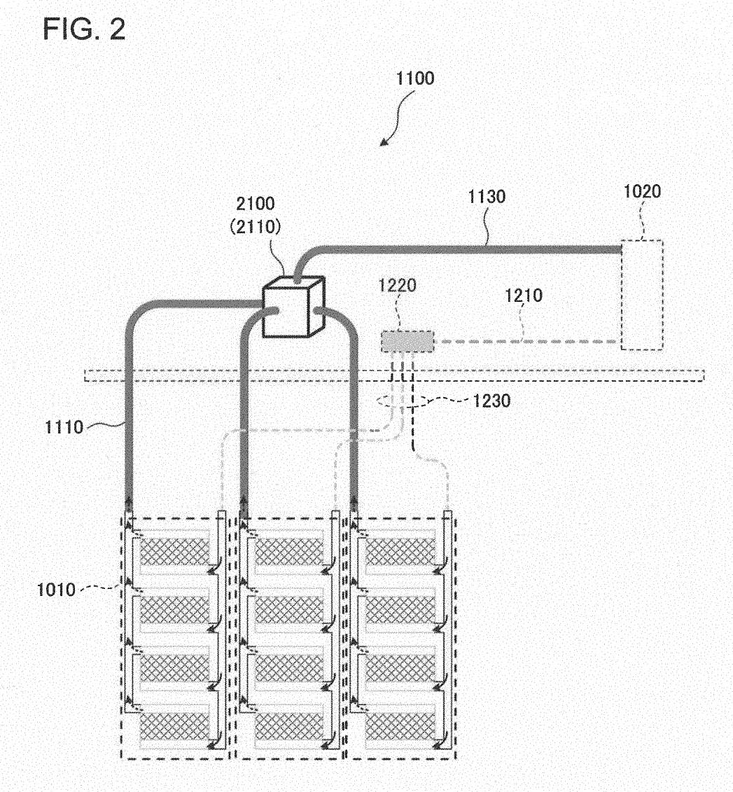

FIG. 2 illustrates the configuration of the refrigerant vapor transport structure 1100 according to the present example embodiment. The refrigerant vapor transport structure 1100 according to the present example embodiment includes a plurality of sub-vapor-pipes 1110, a vapor joining portion 2100, and a main-vapor-pipe 1130. The plurality of sub-vapor-pipes 1110 are respectively connected to the plurality of heat receiving units 1010. The plurality of sub-vapor-pipes 1110 are connected to the vapor joining portion 2100, where the refrigerant vapor streams meet that flow in through the plurality of sub-vapor-pipes 1110 and have been generated in the respective heat receiving units 1010. The main-vapor-pipe 1130 connects the vapor joining portion 2100 to the condensing unit 1020.

In the refrigerant vapor transport structure 1100 according to the present example embodiment, the vapor joining portion 2100 is configured to include a container 2110 with a solid shape having a plurality of flat surfaces, a main-vapor-pipe connection, and a plurality of sub-vapor-pipe connections. The main-vapor-pipe connection is located on the upper surface of the container 2110 and is connected to the main-vapor-pipe 1130. The plurality of sub-vapor-pipe connections are located on the side surfaces of the container 2110 and are respectively connected to the plurality of sub-vapor-pipes 1110.

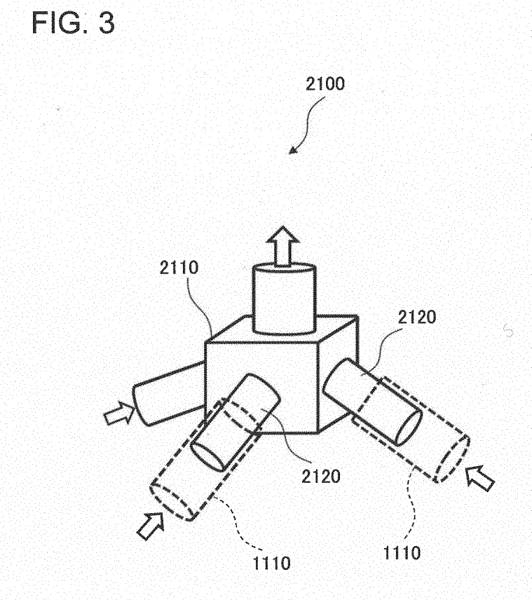

FIG. 3 illustrates the configuration of the vapor joining portion 2100 according to the present example embodiment. The vapor joining portion 2100 includes connecting protrusions 2120 in the main-vapor-pipe connection and the sub-vapor-pipe connections, respectively. That is to say, the vapor joining portion 2100 includes the container 2110 with a solid shape having a plurality of planar sections, and the connecting protrusions 2120 are attached to the respective planar sections composing the main-vapor-pipe connection and sub-vapor-pipe connections. The connecting protrusions 2120 can be made a nozzle shape, for example. The sub-vapor-pipes 1110 are respectively connected to the ends of the connecting protrusions 2120. The arrows in FIG. 3 indicate the flow directions of the refrigerant vapor.

The connecting protrusion 2120 (nozzle) can be configured to be detachable, and its diameter can be selected depending on the amount of heat generation of each heat source to which each heat receiving unit 1010 is thermally connected. That is to say, the vapor joining portion 2100 can be configured to include at least two sub-vapor-pipe connections with the connecting protrusions 2120 differing from each other in the diameter. This enables the sub-vapor-pipe 1110 connected to the heat receiving unit 1010 with a large amount of heat generation to be connected to the container 2110 by the connecting protrusion 2120 having a large diameter. In other words, the optimum diameter of the connecting protrusion 2120 included in the main-vapor-pipe connection and the sub-vapor-pipe connection can be selected depending on the amount of the refrigerant vapor generated in the heat receiving units 1010. As a result, it is possible to reduce the pressure loss of the refrigerant vapor before and after the confluence and transport the refrigerant successfully.

The main-vapor-pipe connection located on the upper surface of the container 2110 can be configured to be located on the extended line of the central axes of the connecting protrusions 2120 included in the sub-vapor-pipe connections on the side surfaces of the container 2110. In other words, the angle at which each connecting protrusion 2120 (nozzle) is attached to the container 2110 can be selected. For example, it is possible to attach the connecting protrusion 2120 (nozzle) to the side surface of the container 2110 at an angle so that the main-vapor-pipe connection may be located on the extended line of the central axes of the connecting protrusion 2120 (nozzle) on the side surface of the container 2110. This makes it possible to control the pressure loss caused by the fact that the refrigerant vapor curves inside the container 2110.

As mentioned above, according to the phase-change cooling device 1000 including the refrigerant vapor transport structure 1100 of the present example embodiment, it is possible to reduce the pressure loss caused by the fact that the refrigerant vapor streams meet that flow into through the plurality of sub-vapor-pipes 1110. As a result, it is possible to cool efficiently even a plurality of heat sources to be cooled by a natural-circulation type phase-change cooling system without degrading the cooling performance.

The connecting protrusion 2120 may be configured to include a flange section at one end. In this case, the main-vapor-pipe connection includes the connecting protrusion 2120 with the flange section fixed on the upper surface of the container 2110 by a fastener member. The sub-vapor-pipe connection includes the connecting protrusion 2120 with the flange section fixed on the side surface of the container 2110 by a fastener member.

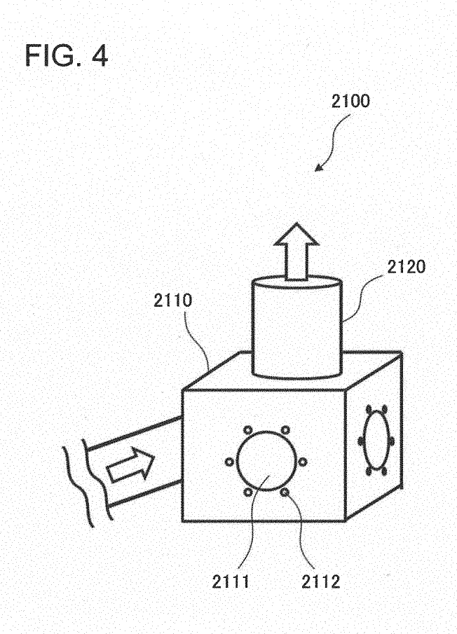

Specifically, for example, as illustrated in FIG. 4, the configuration can be used in which an incurrent hole 2111 for the refrigerant vapor and a screw hole 2112 to attach the flange section of the connecting protrusion 2120 are formed on the side surface of the container 2110 composing the vapor joining portion 2100. This makes it easy to attach and detach the connecting protrusions 2120 (nozzle) having a desired diameter. If there are a few of the heat receiving units 1010 to which the sub-vapor-pipes 1110 are connected, an unwanted connecting protrusion 2120 (nozzle) may be detached, and the incurrent hole 2111 may be sealed with a lid or the like.

Similarly, the main-vapor-pipe connection to be connected to the main-vapor-pipe 1130 can be configured to include a connecting protrusion 2120 having a flange section. It becomes easy again to select a desired diameter because it is possible to attach and detach the connecting protrusion 2120 easily.

The configuration has been described above in which the connecting protrusion 2120 includes a flange section at one end. It is not limited to this, however, it may be configured that the sub-vapor-pipe 1110 includes a flange section at one end. The container 2110 can be configured to include, on the side surface, a connecting hole to fix the above-described sub-vapor-pipe 1110 by means of a fastener member. In this case, the flange section of the sub-vapor-pipe 1110 and the connection hole compose the sub-vapor-pipe connection.

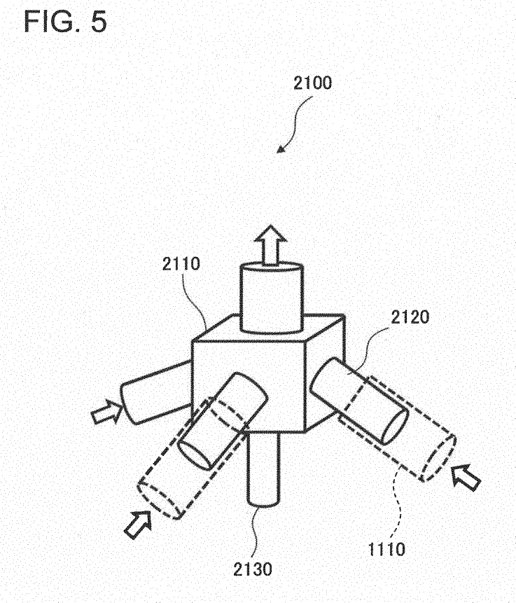

As illustrated in FIG. 5, the vapor joining portion 2100 may be configured to further include a branch pipe 2130 connected to the refrigerant liquid transport structure 1200. Through the branch pipe 2130, the condensed refrigerant liquid that arises in the vapor joining portion 2100 and the main-vapor-pipe 1130 is transported to the liquid pipe side. This can prevent the refrigerant liquid from flowing back to the heat receiving units 1010. It is possible to decrease the fluid resistance to the refrigerant vapor due to the presence of refrigerant liquid in the refrigerant vapor transport structure 1100, which enables the thermal transport efficiency to improve.

### A Third Example Embodiment

Next, a third example embodiment of the present invention will be described. In the present example embodiment, the refrigerant vapor transport structure 1100 included in the phase-change cooling device 1000 will be described further in detail.

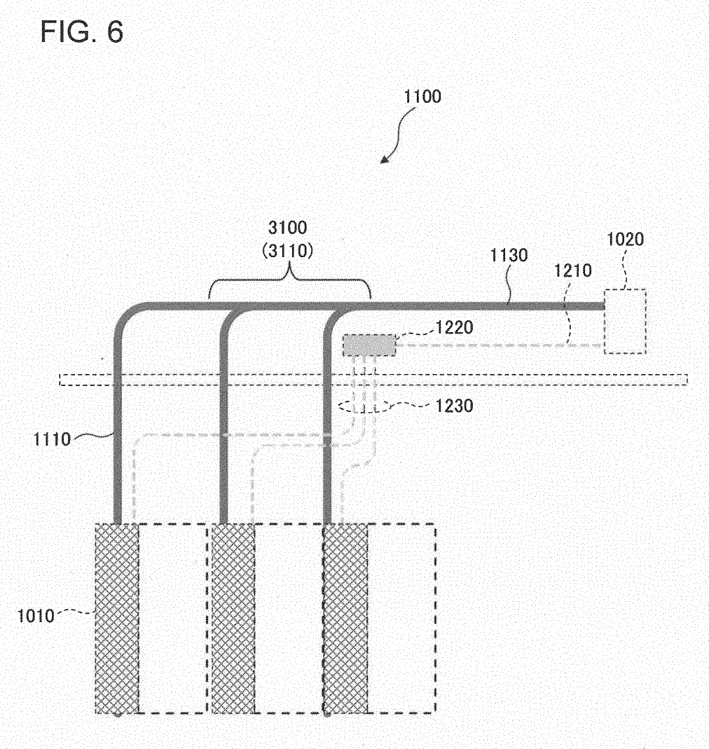

FIG. 6 illustrates the configuration of the refrigerant vapor transport structure 1100 according to the present example embodiment. The refrigerant vapor transport structure 1100 according to the present example embodiment includes a plurality of sub-vapor-pipes 1110, a vapor joining portion 3100, and a main-vapor-pipe 1130. The plurality of sub-vapor-pipes 1110 are respectively connected to the plurality of heat receiving units 1010. The plurality of sub-vapor-pipes 1110 are connected to the vapor joining portion 3100, where the refrigerant vapor streams meet that flow in through the plurality of sub-vapor-pipes 1110 and have been generated in the respective heat receiving units 1010. The main-vapor-pipe 1130 connects the vapor joining portion 3100 to the condensing unit 1020.

In the refrigerant vapor transport structure 1100 according to the present example embodiment, the vapor joining portion 3100 is configured to include a piping area 3110 and to be connected to the plurality of sub-vapor-pipes 1110 on the side of the piping area 3110.

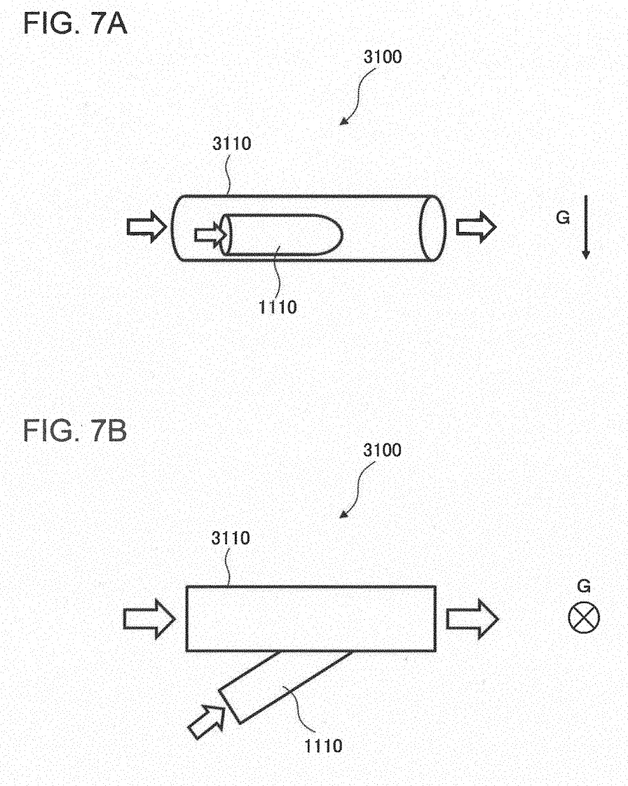

FIG. 7A and FIG. 7B illustrate the configuration of the vapor joining portion 3100 according to the present example embodiment. FIG. 7A is a side view, in which a downward direction on paper is the direction of gravitational force G (vertical downward direction). FIG. 7B is a top view, in which a direction in depth on paper is the direction of gravitational force G (vertical downward direction). The arrows in the figures represent the flow directions of the refrigerant vapor.

As illustrated in FIGS. 7A and 7B, the piping area 3110 included in the vapor joining portion 3100 has a diameter larger than that of the sub-vapor-pipes 1110. This makes it possible to control elevated internal pressure even though the refrigerant vapor flows into the piping area 3110 through the plurality of sub-vapor-pipes 1110.

The vapor joining portion 3100 is configured so that the flow direction of the refrigerant vapor flowing into the piping area 3110 from the sub-vapor-pipe 1110 may make an acute angle on the same plane with the flow direction of the refrigerant vapor flowing through the piping area 3110. In addition, the vapor joining portion 3100 can be configured so that the central axis of the stream of the refrigerant vapor flowing into the piping area 3110 from the sub-vapor-pipe 1110 may not intersect the central axis of the piping area 3110.

That is to say, the vapor joining portion 3100 can be configured in which each of the sub-vapor-pipes 1110 connected to the plurality of heat receiving units 1010 is attached to the piping area 3110 in an oblique direction and is eccentrically attached. In other words, the sub-vapor-pipes 1110 are attached to the piping area 3110 with those central axes out of alignment. Thus, the configuration in which the central axes of the piping area 3110 and the sub-vapor-pipes 1110 are out of alignment makes it possible to prevent the refrigerant vapor streams from colliding in the portion where the dynamic pressure of the refrigerant vapor is highest; therefore, it is possible to control elevated internal pressure.

In particular, the configuration in which the refrigerant vapor streams meet in an oblique direction with those central axes out of alignment enables the refrigerant vapor flowing from the sub-vapor-pipe 1110 to meet, tracing a spiral, with the refrigerant vapor flowing from the upstream position of the piping area 3110 along its migration direction. This makes it possible to control the pressure loss caused by the collision between the refrigerant vapor streams and prevent the absorption performance to degrade.

As mentioned above, according to the phase-change cooling device 1000 with the refrigerant vapor transport structure 1100 including the vapor joining portion 3100 in the present example embodiment, it is possible to reduce the pressure loss caused by the fact that the refrigerant vapor streams meet that flow into through the plurality of sub-vapor-pipes 1110. As a result, it is possible to cool efficiently even a plurality of heat sources to be cooled by a natural-circulation type phase-change cooling system without degrading the cooling performance.

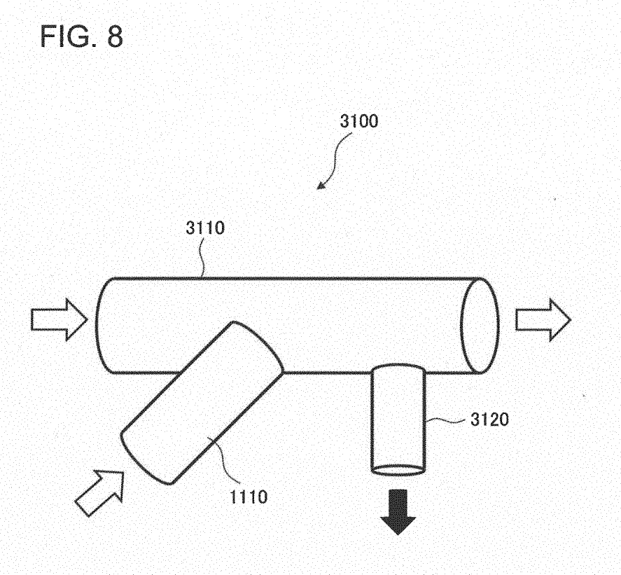

As illustrated in FIG. 8, the vapor joining portion 3100 may be configured to further include a branch pipe 3120 connecting the piping area 3110 to the refrigerant liquid transport structure 1200. In FIG. 8, the white arrow represents the flow direction of the refrigerant vapor, and the black arrow represents the flow direction of the refrigerant liquid.

Through the branch pipe 3120, the condensed liquid of the refrigerant that arises in the piping area 3110 is transported to the liquid pipe side. This can prevent the refrigerant liquid from flowing back to the heat receiving units 1010. It is possible to decrease the fluid resistance to the refrigerant vapor due to the presence of refrigerant liquid in the refrigerant vapor transport structure 1100, which enables the thermal transport efficiency to improve.

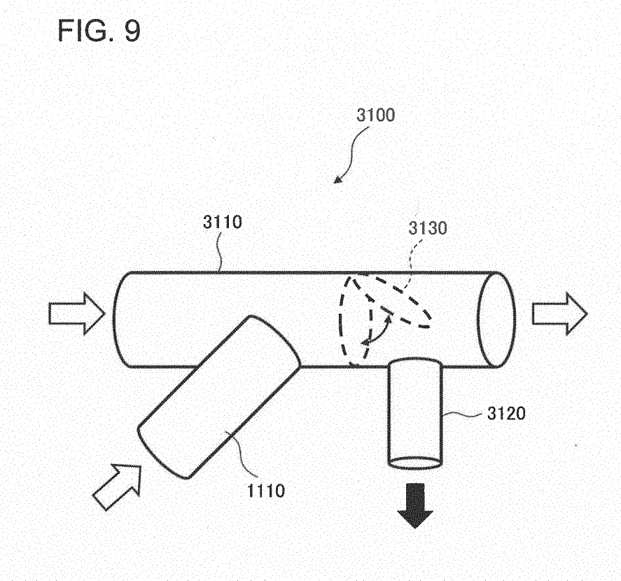

As illustrated in FIG. 9, the piping area 3110 can be configured to include a check valve 3130. The check valve 3130 is located between a connection with the plurality of sub-vapor-pipes 1110 and a connection with the branch pipe 3120 inside the piping area 3110. The configuration makes it possible to prevent the refrigerant liquid from flowing to the heat receiving units 1010 through the sub-vapor-pipes 1110 by making the check valve 3130 a closed condition, even though the condensed refrigerant liquid flows back. It becomes possible to drain certainly the refrigerant liquid out into the refrigerant liquid transport structure 1200 through the branch pipe 3120.

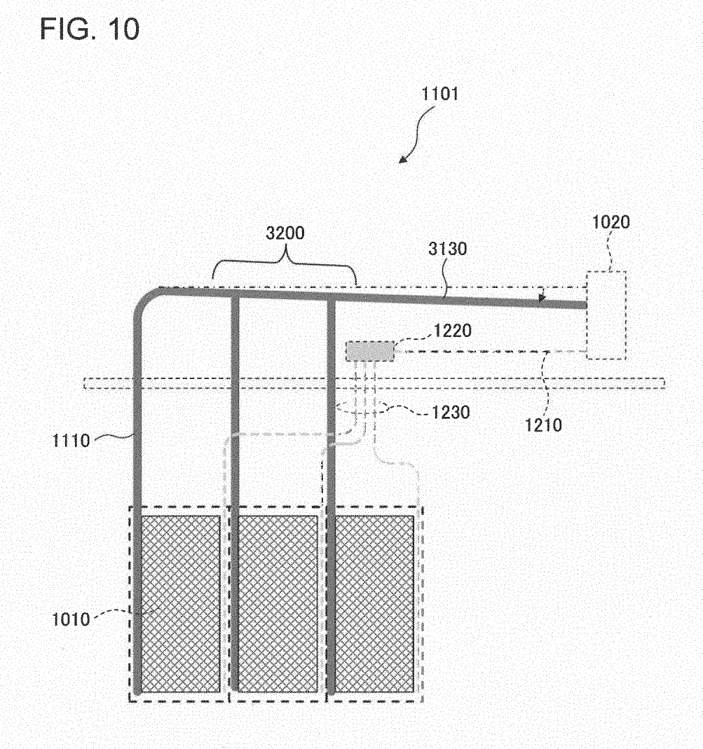

FIG. 10 illustrates another configuration of the refrigerant vapor transport structure according to the present example embodiment. The refrigerant vapor transport structure 1101 illustrated in FIG. 10 includes a plurality of sub-vapor-pipes 1110, a vapor joining portion 3200, and a main-vapor-pipe 3130. The vapor joining portion 3200 includes a piping area and is connected to the plurality of sub-vapor-pipes 1110 on the side surface of the piping area. As illustrated in FIG. 10, the vapor joining portion 3200 and the main-vapor-pipe 3130 are disposed along a slope heading for the vertically lower side toward the condensing unit 1020.

The configuration enables the refrigerant liquid in the vapor joining portion 3200 and the main-vapor-pipe 3130 to flow to the condensing unit 1020. As a result, it is possible to decrease the fluid resistance to the refrigerant vapor due to the presence of refrigerant liquid in the refrigerant vapor transport structure 1101, which enables the thermal transport efficiency to improve.

The present invention has been described using the above-mentioned example embodiments as exemplary examples. The present invention, however, is not limited to the above-mentioned example embodiments. That is to say, various aspects that can be understood by those skilled in the art can be applied to the present invention within the scope of the present invention.

This application is based upon and claims the benefit of priority from Japanese patent application No. 2014-172114, filed on Aug. 27, 2014, the disclosure of which is incorporated herein in its entirety by reference.

### REFERENCE SIGNS LIST

1000 phase-change cooling device
1010 heat receiving unit
1020 condensing unit
1100, 1101 refrigerant vapor transport structure
1110 sub-vapor-pipe
1120, 2100, 3100, 3200 vapor joining portion
1130, 3130 main-vapor-pipe
1200 refrigerant liquid transport structure
1210 main-liquid-pipe
1220 refrigerant liquid reservoir
1230 sub-liquid-pipe
2110 container
2111 incurrent hole
2112 screw hole
2120 connecting protrusion
2130, 3120 branch pipe
3110 piping area
3130 check valve

1. A phase-change cooling device, comprising:
a plurality of heat receiving units configured to receive heat;
a condensing unit configured to radiate heat; and
a first refrigerant pathway and a second refrigerant pathway connecting the plurality of heat receiving units to the condensing unit;
wherein the first refrigerant pathway includes
a plurality of sub-refrigerant-pipes respectively connected to the plurality of heat receiving units,
a refrigerant joining portion connected to the plurality of sub-refrigerant-pipes, and
a main-refrigerant-pipe connecting the refrigerant joining portion to the condensing unit.

2. The phase-change cooling device according to claim 1,
wherein refrigerant vapor and refrigerant liquid circulate through the heat receiving units, the condensing unit, the first refrigerant pathway, and the second refrigerant pathway.

3. A phase-change cooling device, comprising:
a plurality of heat receiving units configured to hold respectively refrigerant receiving heat from a plurality of heat sources;
a condensing unit configured to generate refrigerant liquid by condensing and liquefying refrigerant vapor of the refrigerant evaporated in the heat receiving units;
a refrigerant vapor transport structure configured to connect the heat receiving units to the condensing unit and transport the refrigerant vapor;
a refrigerant liquid transport structure configured to connect the heat receiving units to the condensing unit and transport the refrigerant liquid;
wherein the refrigerant vapor transport structure includes
a plurality of sub-vapor-pipes respectively connected to the plurality of heat receiving units,
a vapor joining portion connected to the plurality of sub-vapor-pipes, with the refrigerant vapor meeting, and
a main-vapor-pipe connecting the vapor joining portion to the condensing unit.

4. The phase-change cooling device according to claim 3,
wherein the vapor joining portion is positioned above the plurality of heat receiving units.

5. The phase-change cooling device according to claim 3,
wherein the vapor joining portion includes
a container with a solid shape having a plurality of flat surfaces including at least a upper surface, a lower surface, and a side surface;
a main-vapor-pipe connection located on at least one of the upper surface and the side surface and connected to the main-vapor-pipe, and
a plurality of sub-vapor-pipe connections located on at least one of the side surface and the lower surface and connected to each of the plurality of sub-vapor-pipes.

6. The phase-change cooling device according to claim 5,
wherein each of the main-vapor-pipe connection and the sub-vapor-pipe connections includes a connecting protrusion.

7. The phase-change cooling device according to claim 6,
wherein the vapor joining portion includes at least two pieces of the sub-vapor-pipe connections with the connecting protrusions differing from each other in a diameter.

8. The phase-change cooling device according to claim 6,
wherein the connecting protrusion includes a flange section at one end,
the main-vapor-pipe connection includes the connecting protrusion with the flange section fixed on the upper surface of the container by a fastener member, and
the sub-vapor-pipe connection includes the connecting protrusion with the flange section fixed on the side surface of the container by a fastener member.

9. The phase-change cooling device according to claim 6,
wherein the main-vapor-pipe connection is located on an extended line of a central axis of the connecting protrusions included in the sub-vapor-pipe connections.

10. The phase-change cooling device according to claim 5,
wherein each of the plurality of sub-vapor-pipes includes a flange section,
the container includes, on the side surface, a connecting hole for fixing by a fastener member, and
each of the plurality of sub-vapor-pipe connections includes the flange section and the connecting hole.

11. The phase-change cooling device according to claim 3,
wherein the vapor joining portion includes a piping area,
the piping area is connected to the plurality of sub-vapor-pipes on a side of the piping area, and
the piping area has a diameter larger than a diameter of each of the plurality of sub-vapor-pipes.

12. The phase-change cooling device according to claim 11,
wherein a flow direction of the refrigerant vapor flowing into the piping area from each of the plurality of sub-vapor-pipes makes an acute angle on a same plane with a flow direction of the refrigerant vapor flowing through the piping area.

13. The phase-change cooling device according to claim 11,
wherein a central axis of a stream of the refrigerant vapor flowing into the piping area from each of the plurality of sub-vapor-pipes does not intersect a central axis of the piping area.

14. The phase-change cooling device according to claim 11,
wherein the vapor joining portion further includes a branch pipe connecting the piping area to the refrigerant liquid transport structure, and
the piping area includes a check valve located between a connection with each of the plurality of sub-vapor-pipes and a connection with the branch pipe.

15. The phase-change cooling device according to claim 3,
wherein the vapor joining portion further includes a branch pipe connected to the refrigerant liquid transport structure.

16. The phase-change cooling device according to claim 3,
wherein the vapor joining portion and the main-vapor-pipe are disposed along a slope heading for a lower side toward the condensing unit.

17. The phase-change cooling device according to claim 3,
wherein each of the plurality of heat receiving units includes a plurality of evaporating units each of which is thermally connected to each of the plurality of heat sources and stores the refrigerant, and
the plurality of evaporating units are disposed in a vertical direction.

18. A phase-change cooling method, comprising:
evaporating refrigerant by receiving heat from each of a plurality of heat sources,
making refrigerant vapor streams of the refrigerant evaporated by each of the plurality of heat sources meet;
generating refrigerant liquid by condensing and liquefying joined refrigerant vapor; and
circulating the refrigerant liquid so as to receive heat from each of the plurality of heat sources.

19. The phase-change cooling device according to claim 4,
wherein the vapor joining portion includes
a container with a solid shape having a plurality of flat surfaces including at least a upper surface, a lower surface, and a side surface;
a main-vapor-pipe connection located on at least one of the upper surface and the side surface and connected to the main-vapor-pipe, and
a plurality of sub-vapor-pipe connections located on at least one of the side surface and the lower surface and connected to each of the plurality of sub-vapor-pipes.

20. The phase-change cooling device according to claim 7,
wherein the connecting protrusion includes a flange section at one end,
the main-vapor-pipe connection includes the connecting protrusion with the flange section fixed on the upper surface of the container by a fastener member, and
the sub-vapor-pipe connection includes the connecting protrusion with the flange section fixed on the side surface of the container by a fastener member.
